(19) United States
(12) Patent Application Publication
(10) Pub. No.: US 2016/0145741 A1
(43) Pub. Date: May 26, 2016

(54) INJECTION NOZZLE FOR AEROSOLS AND THEIR METHOD OF USE TO DEPOSIT DIFFERENT COATINGS VIA VAPOR CHEMICAL DEPOSITION ASSISTED BY AEROSOL

(71) Applicant: Centro de Investigación en Materiales Avanzados, S.C., Chihuahua (MX)

(72) Inventors: Mario MIKI YOSHIDA, Chihuahua (MX); Oscar VEGA BECERRA, Nuevo Leon (MX); Patricia AMEZAGA MADRID, Chihuahua (MX); Pedro PIZA RUIZ, Chihuahua (MX)

(21) Appl. No.: 14/925,299

(22) Filed: Oct. 28, 2015

(30) Foreign Application Priority Data
Oct. 30, 2014 (MX) MX/A/2014/013233

(51) Int. Cl. C23C 16/448; C23C 16/40; B05B 1/02; B05D 1/00; B05B 1/24

(52) U.S. Cl. CPC C23C 16/4486; B05D 1/60; B05B 1/24; B05B 1/02; C23C 16/405

(57) ABSTRACT

This invention relates to an aerosol injection nozzle designed with a specific geometry to place materials vertically “upwards”, i.e., in opposite direction to the gravity and its method of use. With the nozzle is possible to deposited coatings, multilayer, composite materials, nanopins, nanorods, nanoclusters, nanoplates, nanowires, nanoparticles, “quantum dots” or semiconductors confined, of different materials, not limited to the examples above: TiO₂ oxides, ZnO, ZrO₂, SnO₂, CuO, NiO, CrOx, AlOx, PbZrTiO₃, LiNbO₃; noble metal Ag, Au, Pt; polymer PANI, PEDOT. The process can be repeated in successive stages with the same device and with the same method to get one or several coatings or materials in successive stages.

### OBJECT OF THE INVENTION

The present invention relates to an injection nozzle for aerosols made of stainless steel with a specific designed geometric and its method of use to uniform and homogeneous deposit coating of different materials (oxides, noble metals, polymers, etc) in layers or multi layers, which may have different nanostructure morphologies such as composite materials, nanopins, nanorods, nanoclusters, nanoplates, nanowires, nanoparticles, quantum dots (confined semiconductors), by the technique of aerosol assisted chemical vapor deposition (AACVD) for its acronym in English.

### BACKGROUND

The aerosol assisted chemical vapor deposition (AACVD) method, is a physical-chemical process, which is a variant of the conventional CVD method. The main difference of the aerosol-assisted variant is that the transport of the precursor or precursors to the deposit zone is made by using a cloud of micrometric drops (aerosol) of the precursor solution carry by a carrier gas. With it can be deposited coatings, thin layers, multilayer, composite materials, nanostructures (nanopins, nanorods, nanoclusters, nanoplates, nanowires, nanoparticles, quantum dots (confined semiconductors), of different materials: for example oxides TiO₂, ZnO, ZrO₂, SnO₂, CuO, NiO, CrOx, AlOx, PbZrTiO₃, LiNbO₃; noble metal Ag, Au, Pt; polyaniline polymers (PANI), poly(3,4-ethylenedioxythiophene) (PEDOT). The AACVD includes forming an aerosol cloud from a solution through a nebulizer which can be ultrasonic, electrostatic, or pneumatic. The precursor solution contains an organic or inorganic salt of the component or material to be deposited and the appropriate solvent. The aerosol formed from this precursor is transported by means of a carrier gas (air, nitrogen, argon, oxygen or mixtures) and is distributed over the substrate surface. A heating platen, which is a uniform and constant temperature, allows to raise the temperature of the substrate, which maintains a relative longitudinal movement with respect to the nozzle. The nozzle perpendicularly injects the aerosol or the reactants to the surface of the substrate, and evenly in the transverse direction, allowing the uniform deposit of the materials in conjunction with the relative longitudinal displacement of the nozzle and the substrate. The system employs a gas hood which allows the evacuation of the by-product gases of the reaction.

One of the problems associated with coating flat substrates using AACVD is associated with keeping the uniformity of the coating thickness through the length and width of the substrate. In many cases, the lack of thickness uniformity creates an undesirable optical effect, an anti-aesthetic appearance of the substrate, and significant differences in optical and electrical properties of the coating. In order to form a coating of uniform thickness, it is necessary that the atomized solution (aerosol) be applied evenly and uniformly on the entire surface of the substrate. To achieve this objective, various devices or equipment have been developed to apply the aerosol evenly over the entire surface of the substrate. Many studies have been published where different deposit systems are reported by the AACVD method. For example in the chapter, “ Aerosols processing of nanostructured oxides for environmental applications” by M. Miki Yoshida and colleagues, published in the book “Aerosols”, ISBN: 978-1-63117-513-8 (e-book), by Nova Science Publishers, Inc. of New York in 2014, is described in a general way the process in the laboratory. Other works describe in more detail the influence of the nozzle in the distribution of the aerosol, in particular in the publication, “Growth and structure of tin dioxide thin films obtained by an improved aerosol pyrohydrolysis technique” written by M. Miki Yoshida and E. Andrade, published in the magazine Thin Solid Films in the volume 224, year 1993, pages 87-96, discussed the selection of the aerosol size caused by the geometry, the nozzle configuration and the pneumatic nebulizer being used. The differences with the present invention is that the nozzle opening is circular and covers the entire surface of the substrate, which is fixed and there is no relative displacement with the nozzle. Other reports using direct nozzles with periodic movements at constant speed which distribute the aerosol over the surface of the substrate, for example in “Synthesis and structural characterization of undoped and co-doped zinc oxide thin films obtained by aerosol assisted chemical vapor deposition” P. Amezaga Madrid and colleagues, published in the Magazine Journal of Alloys and Compounds, volume 483, year 2009, pages 410-413. The differences with the present invention are that the nozzle of the publication does not include horizontal plates parallel to the substrate that increases the region where the reactants can spread, react, and combine on the surface of the substrate; and neither includes heat transmission fins towards the walls of the nozzle. Another difference is that the nozzle moves to evenly distribute the aerosol over the substrate.

On the other hand, many patents that are of public domain cite, mention, or involve the use of a method, apparatus, device, or accessory that improves or controls coating uniformity via AACVD. By example in U.S. Pat. No. 5,190,592, it discloses a system to inject aerosol drops, which contains a solute for the production of a layer of a composite material, produced by the pyrolysis of the solute onto the hot substrate surface. The main differences with the present invention are: a) the “upward” position of the nozzle of the present invention, which prevents possible contamination of the coating deposited with the particles of the solute or other material and the elimination of vortices in the gas flow, as happens in the case of injections facing down. (b) the nozzle of the present invention comprises of horizontal plates parallel to the substrate that increases the area where the reactants can spread, react, and combine over the surface of the substrate. (c) the same horizontal plates have heat transmission fins towards the walls of the nozzle, allowing their heating, and as a result the aerosol transported inside improving the speed and efficiency of the deposit of the precursor. In the mentioned patent, heating resistances are used in order to preheat the aerosol flow.

Another U.S. Pat. No. 6,521,047 B1 discloses a device to provide a liquid precursor or in a solution for a CVD installation. The difference of this reference is that it includes an evaporation chamber containing heat resistances to evaporate the precursors. U.S. Pat. No. 6,277,201 B1 discloses a CVD apparatus to form a thin film using a liquid precursor, which mainly includes: a reaction chamber, a vacuum system connected to the chamber, a liquid precursor atomization-vaporization system. The advantages of the present invention in relation to the mentioned patent are: they do not require a vacuum system, nor a vaporization device for the liquid precursor. U.S. Pat. No. 6,210,485 B1 is related to a device and process for the vaporization of liquid precursors and the deposit of a film on a suitable substrate; similarly uses heating elements for the vaporization section. U.S. Pat. No. 5,945,162 has as the main objective to provide a device to introduce the precursors to the inside of the CVD chamber. The proposed method comprises to keep one or more liquid precursors in a solution to a higher pressure than the pressure of the deposit chamber; injecting regularly and controlled to the chamber drops of the precursor of a predetermined volume; volatilize the injected drops to produce evaporated precursors; which are transported towards the substrate to the pressure and temperature of the chamber. The differences with the present invention are: a) in the mentioned patent there are zones of different pressures, while in the present invention the entire process occurs at a pressure near atmospheric pressure. A device is necessary to maintain the pressure of the precursor to a higher pressure than that of the chamber. (b) the aforementioned patent uses a drops periodic injection system, while the present invention uses a nebulization system for the precursor. (c) the aforementioned patent uses a heating plate where being projected to the drops produces its vaporization.

Another U.S. Pat. No. 4,351,267 which claims the use of a three conducts nozzle, each conduct with an output having a straight slot opening and having side walls that delimit the edges of each slot and whose walls converge towards a common line of the three conducts. Also, it is claimed that the width of each of the slots that constitute the exhaust opening must not be less than 0.1 mm and not more than 0.2 mm. The differences with the present invention are: a) the nozzle of the present invention has horizontal plates parallel to the substrate that enhances the area where the reactants can spread, react and combine on the surface of the substrate. (b) the same horizontal plates have heat transmission fins towards the walls of the nozzle, allowing the same heating of the same, and as a result, the aerosol transported to the inside of it is preheated, improving the speed and efficiency of the deposit of the precursor.

### BRIEF DESCRIPTION OF THE FIGURES

FIG. 1 shows a typical side diagram of an “upwards” AACVD system.

FIG. 2 shows an isometric view diagram of the improved device of the present invention.

FIG. 3 shows a bottom view indicating the dimensions of the entrance and exit sections of the nozzle.

FIG. 4 is a photograph showing a front view of the improved device or injection nozzle of the present invention.

FIG. 5 is a top view of the injection nozzle of the present invention.

FIG. 6 is a picture that shows an example of coating of Ti dioxide (14), deposited on a glass substrate (3) on 40×33 cm² surface, retrieved using the nozzle injection of the present invention at an AACVD pilot plant.

### DETAILED DESCRIPTION OF THE INVENTION

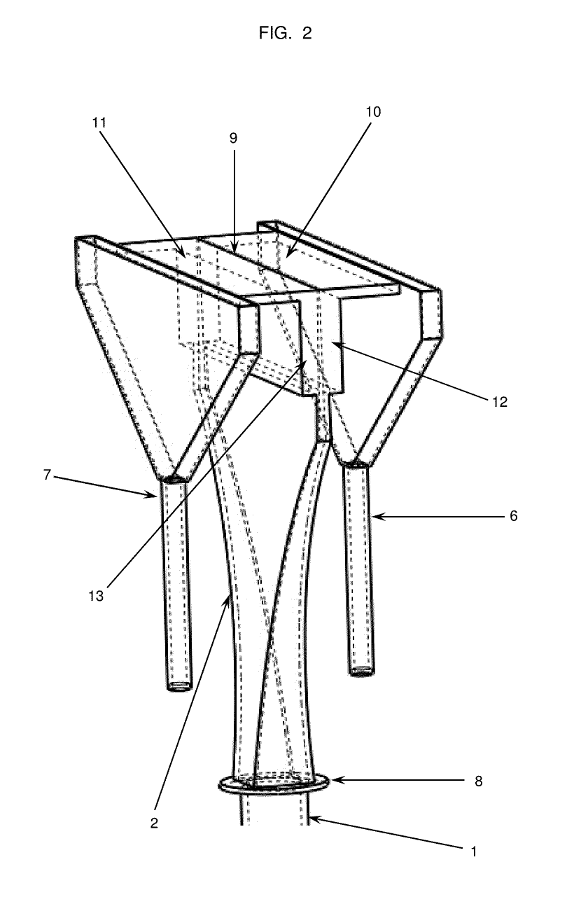

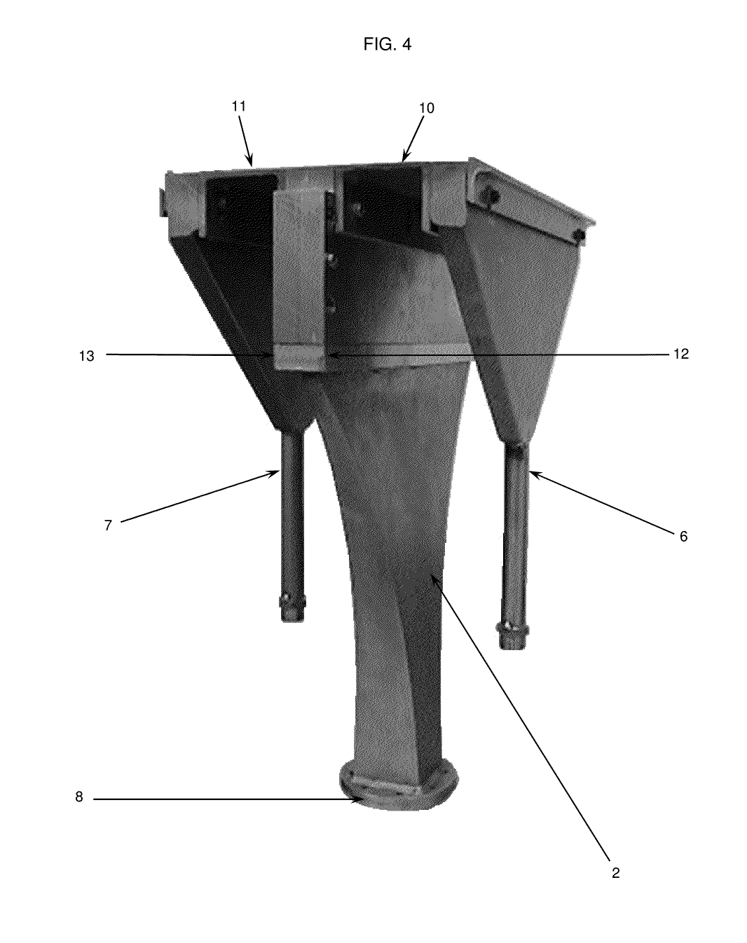

The injection nozzle for aerosols of the present invention, which is completely represented in FIGS. 2 and 4, is designed to deposit materials in a vertical manner “upwards” i.e., in the opposite direction to the gravity.

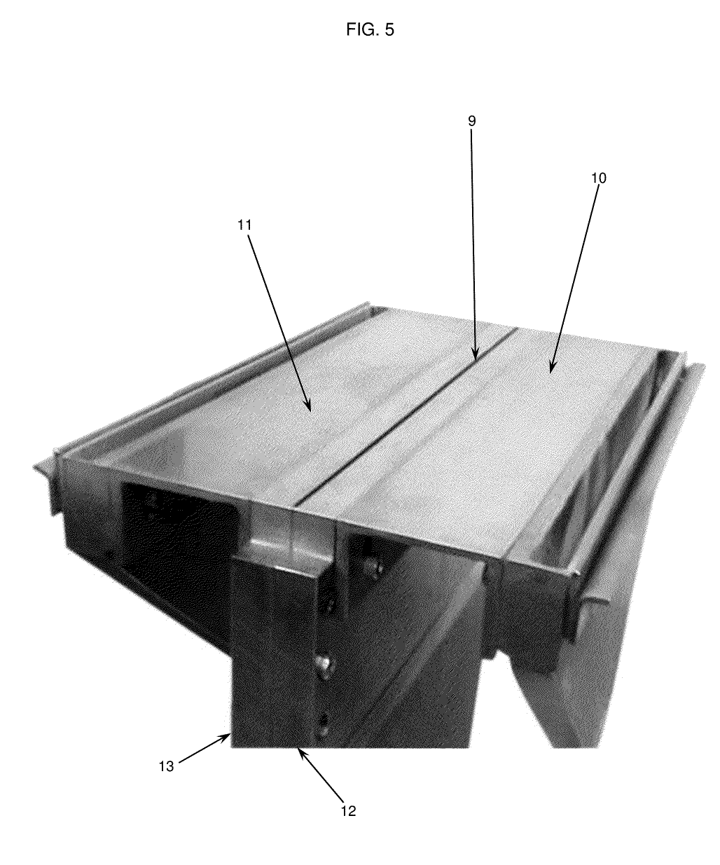

Includes one square section (8), located in the center portion of its lower end, where this section is connected by its lower end with a nebulizer (1), being the output section of the nozzle a tip (9) at its upper end. Between the upper and the lower there are two plates having the shape of a fan (2) which in the lower end form the front and back walls of the square section (8) and at its upper end are connected to a front (12) and back (13) heat transmission fins as it can be seen in detail in FIG. 5, which span across the width of the nozzle in the transverse direction. These heat transmission fins (12) (13) are rigidly joined with its lower end to the upper ends of the plates (2) having a fan-shaped while their upper end finishes in the distribution plates (10) (11), found at the upper end of the nozzle at both sides of the tip (9). The left and right lateral sides of the square section are formed by two plates (17) (18) that as they ascend slowly curve outward, following the lateral ends of the fan shaped plates (2) to which are connected and are being progressively narrower.

In addition, includes two distribution plates (10) (11), which are located the upper end of the nozzle, each one on a side of the tip (9) transversally spanning across the entire width of the upper end of the nozzle, and longitudinally extending from the heat transmission fins (12) (13) to the extraction ducts (15) (16) of rectangular section, which are located at the front end and back end of the nozzle and which are hollow elements that at their top end have a rectangular portion that extends down with a trapezoidal portion whose lower end, at its lower end, ends with a cylindrical tube (6) (7).

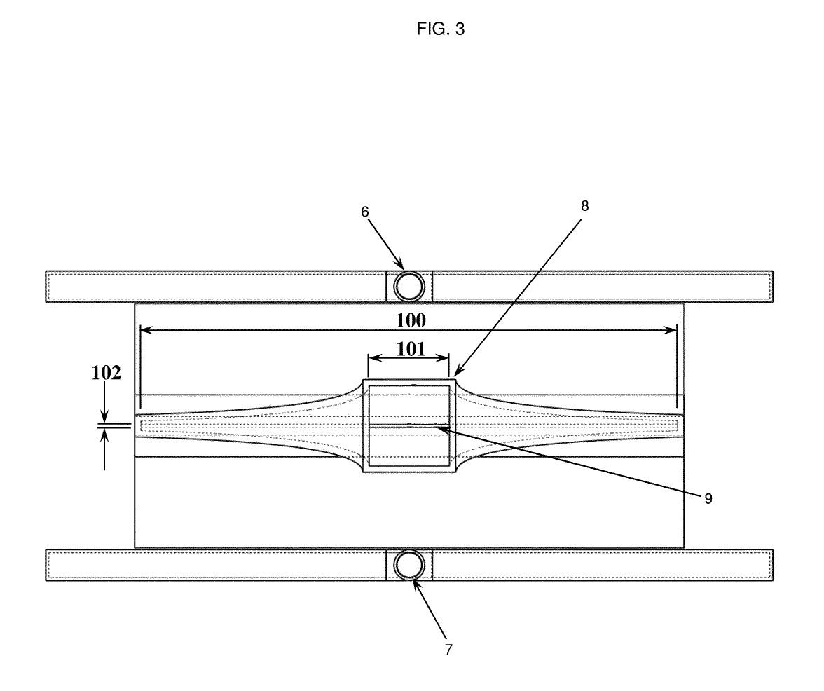

FIG. 3 shows the bottom view of the injection nozzle, showing the input section of the nozzle (8), which is square and which dimension (101) depends on the dimensions of the output end of the nebulizer. While the output section of the tip (9) is rectangular and its length (100) depends on the transverse dimension of the substrate; the size of the opening (102) of the tip (9) is from 1 to 10 mm, the precise value depends on the flow of the nebulized solution and the carrier gas. The profile geometry of the injection nozzle, in the frontal plane, seeing the injection nozzle in the direction of movement of the substrate, i.e. from bottom to top, is designed considering the natural fluid trajectories from the lower dimension, in the lower end (101), until the greater dimension towards the top end (100), i.e. the nozzle walls follow the paths of the flow limits if there is a sudden change of the dimensions of the nozzle from the lower end (101) to the top end (100). In the transverse plane, the dimension gradually changes from the greater dimension at the lower end (101), to the lower dimension at the upper end (102).

### Aerosol Injection Device

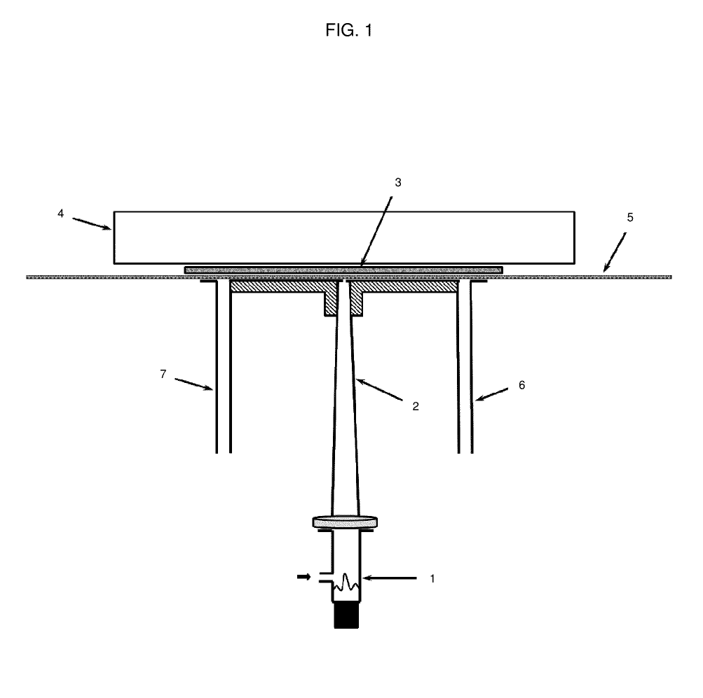

FIG. 1 shows an aerosol injection nozzle AACVD “upwards”, installed in a typical AACVD deposit system. The term “upwards” means that the injection of the precursor in the form of aerosol is done vertically in the opposite direction to the gravity.

FIG. 2 shows in more detail the structure of the aerosol injection nozzle of the present invention. The input section (8) of the injection nozzle, in the lower part, is connected to the nebulizer (1), while the output section (9), on the top section, injects the precursor aerosol transversally over the surface of the substrate. The injection nozzle has two distribution plates (10) and (11), extending wide and longitudinally from the heat transfer fins (12) (13) to the extraction ducts (15) (16) which are located at the ends of the nozzle. The distribution plates (10) and (11), allow to distribute the precursor mist in a larger surface of the substrate, increasing the speed of the deposit and the efficiency of utilization of the precursor.

The front and back ends of the nozzle includes the extraction ducts (6) and (7), which evacuates the by-product gases of the reaction of the precursor and the solvent vapors. In addition, the distribution plates (10) and (11) are equipped with heat transfer fins (12) and (13) towards the upper section of the injection nozzle, which allow the warming of that region of the nozzle, in order to preheat the aerosol flow, prior to the arrival to the surface of the substrate, in order to promote the thermo-chemical process required for the decomposition of the precursor and the deposit of the material. The control of this heating can be done by controlled fluid circulation, by coupled ducts (not shown) to the walls of the nozzle.

The main advantages of this aerosol injection nozzles are: (to) avoid the turbulence formed on the substrate surface generated by the carrier gas-free convection to be heated up as it nears the surface, which is at a higher temperature; b) prevents contamination of the coating deposited due to the precipitation of dust particles from the tip of the injection nozzle, as it occurs on systems running “downward”; (c) simplicity; (d) low implementation cost and operation, since expensive equipment is not necessary, heat resistances, vacuum systems, radio frequency or voltage sources, or temperature control. The distribution plates (10) and (11) parallel to the substrate, increase the region where the reactants can spread, react, and combine on the surface of the substrate. Also, the heat transfer fins (12) and (13) of the distribution plates allow the heating of them, and consequently of the transported aerosol; improving the speed and the efficiency of the deposit of the precursor. Additionally, their dimensions may be modified according to the substrate that needs to be covered.

### Example 1. Use of the Nozzle to Deposit Materials by AACVD Technique

FIG. 1 shows an injection nozzle AACVD “upwards”, installed in a typical AACVD deposit system, which will be used as an example for the description and use of the injection nozzle of the present invention. In the present invention, the synthesis of the materials is performed using the injection nozzle of the present invention to evenly distribute the materials in the transverse direction, which together with the displacement of the substrate (3) in the axial direction, allows the homogeneous deposit of the coatings using the AACVD technique.

### Example 2. Brief Description of the Method of Use

The method includes forming an aerosol mist from a precursor solution through a nebulizer (1) placed underneath the injection nozzle that can be ultrasonic, electrostatic, or pneumatic. The precursor solution contains dispersions or predecessor organic or inorganic salts of the component or material to be deposited, and the appropriate organic or inorganic solvent. The aerosol formed from this precursor is transported by a carrier gas (oxidizing, inert, or reducer) and is distributed by the injection nozzle of the present invention on the surface of the substrate (3), which moves near the heating plate (4) that without forming part of the present invention, with respect to the substrate, is located on the opposite side of the aerosol injection nozzle. The substrate (3) is seated in a mobile system (5) that without being part of the nozzle of the present invention, controls the longitudinal movement of the substrate along the heating plate (4) inserting the substrate (3) by the left side and out the right side. The mobile system (5) can be formed by a rail, a band or chain conveyor, which does not obstruct the bottom section of the aerosol deposit on the surface of the substrate (3). This system allows the gradual heating of the substrate (3) by the heating plate (4), as it approaches the deposit area. The heating plate (4) is a uniform and constant temperature between 100 and 900° C. and raises the temperature of the substrate, allowing the uniform deposit of materials. The injection nozzle injects the aerosol perpendicular to the surface of the substrate, and evenly in the transversal direction to the longitudinal movement of the substrate (3). By the spread and adsorption of the aerosol on the surface of the substrate (3), due to the temperature of it, a thermal decomposition and chemical reaction of the precursor occurs, depositing the material. In the front and back ends of the nozzle can be found the extraction ducts (6) and (7) which eliminates the by-product gases of the reaction of the precursor and the solvent vapors. The system is within a gas extraction hood (not shown in figures) which enables the evacuation of by-product gases of the reaction. This method is carried out on a substrate (3) which can normally be glass, borosilicate, quartz, ceramic, metal, silicon, polymer, or any other material that supports the temperature of the process of 100-900° C. The area of the substrate (3) can vary from mm² up to thousands of cm².

The method of use of the present invention is carried out according to the following steps:
(a) preparing a solution with a precursor salt of materialwhich can be from a chloride, nitrate, acetylacetonate, acetate, or a homogeneous dispersion of nanoparticles and a solvent, chosen from the group of methanol, ethanol, distilled water, or a mixture of them. The concentration of the precursor solution is in the range from 0.001 to 1 mol dm⁻³.
(b) attaching the substrate (3), glass, ceramic, metal, or polymer in the mobile system (5). Setting the travel speed of the belt or chain conveyor (5) from 0.01 to 20 cm min⁻¹.
(c) heating a heating plate (4) between 100 and 900° C. The heating can be in atmospheric air or in a controlled environment, for 15-60 minutes, until the thermal stabilization of the plate. The particular value of the temperature of the plate (4) depends on the precursor material and the nature of the substrate used,
(d) introducing the carrier gas at a flow rate of between 1-100 L min⁻¹ for the thermal stabilization of the entire system, including the nozzle (2) and its heat transfer fins (12) and (13). The particular value of the gas flows depends on the dimensions of the substrate and the other conditions of synthesis.
(e) placing the required amount of precursor solution into the deposit of the nebulizer (1). For deposits of long times, a greater amount of solution can be added during the deposit.
(f) nebulizing the precursor solution to transform it into a mist of fine drops, this mist is transported from the nebulizer (1) to the nozzle (2). At the same time, the movement of the mobile system starts. The movement of the substrate must start outside the distribution plate, to distribute the aerosol evenly throughout all the substrate. Keep the misting of the precursor solution and the movement of the nozzle for the required time, which can be from 1-180 minutes, depending on the material and the coating characteristics.

### Example 3

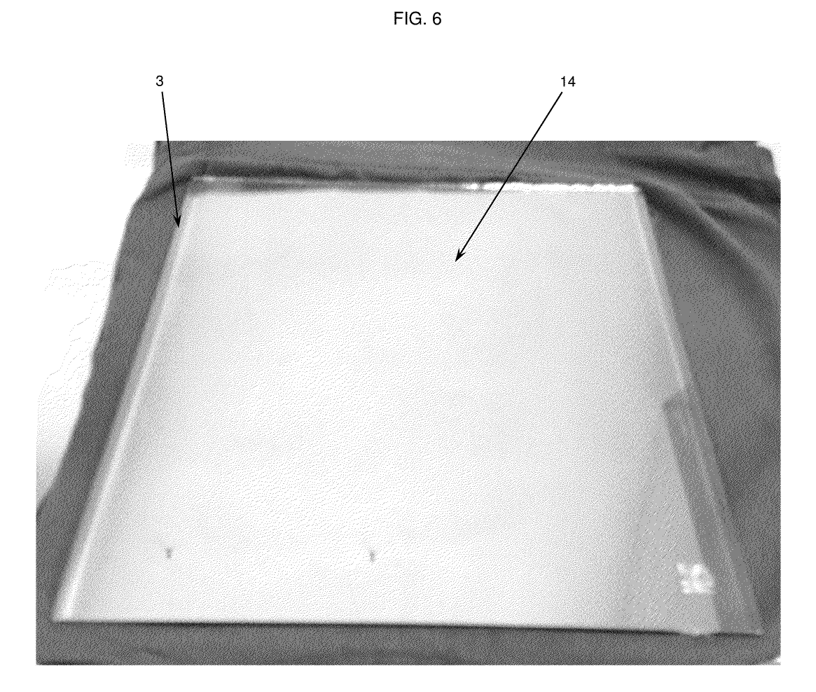

FIG. 6 shows a coating Ti dioxide (14) whose synthesis conditions were: temperature 320° C., the precursor solution molarity 0.035 M, with a carrier gas flow of 50 L min⁻¹ c, and a speed of 0.12 mm sec⁻¹, from approximately 70 nm thick, deposited on a glass substrate (3) of 40×33 cm² surface. It was obtained using the aerosols injection nozzle of the present invention in an AACVD pilot plant. Uniformity of the coating distributed on all surfaces of the substrate can be seen.

The materials that this nozzle can deposit may be: oxides, noble metals, polymers, etc., in the form of layer or multi-layer, with different nanostructures as composite materials, nanopins, nanorods, nanoclusters, nanoplates, nanowires, nanoparticles, quantum dots (confined semiconductors), on substrates of large dimensions, which can be common glass, borosilicate, quartz, silicon, sapphire, ceramic, metal, polymer, or any other material that will resist temperatures of 100° C. to 900° C. necessary for the process. The device or injection nozzle may be used repeatedly to get various coatings or materials in successive stages, changing the precursors and the conditions of the deposit.

More specifically, the aerosols injection nozzle of the present invention allows to deposit coatings, monolayer, multilayer, composite materials, nanopins, nanorods nanoclusters, nanoplates, nanowires, nanoparticles, “quantum dots”, of different materials, not limited to the examples above: oxides TiO₂, ZnO, ZrO₂, SnO₂, CuO, NiO, CrOx, AlOx, PbZrTiO₃, LiNbO₃; noble metal Ag, Au, Pt; polymer PANI, PEDOT, using the chemical vapor deposition “upwards”.

1-10. (canceled)

11. An aerosol injection nozzle for vertically depositing different coatings comprising:
a square section (8) located in a center of a lower end of the nozzle, the square section is connected with a nebulizer (1);
a tip located on an output section of the nozzle (9) located at an upper end of the nozzle;
two fan shaped plates (2) located between the lower end and the upper end of the nozzle, the two fan shaped plates at their lower end form a front wall and a back wall of the square section (8);
front and back heat transfer fins (12) (13) connected to the upper ends of the two fan shaped plates, the front and back heat transfer fins spread across a width of the nozzle in a transverse direction; the heat transfer fins are rigidly joined at the lower ends to the upper end of the fan shaped plates (2);
distribution plates (10) (11) connected to the upper end of the heat transfer fins, the distribution plates are located in the upper end of the nozzle;
a left lateral side and a right lateral of the square section formed by two plates (17) (18) which as going up, gradually curve outward, following lateral sides of the fan shaped plates (2) to which they are attached; the two distribution plates (10) (11) are located at the upper end of the nozzle, each one on one of the sides of the nozzle (9) spanning across an entire width of the upper end of the nozzle, and extending longitudinally from the heat transfer fins (12) (13) to extraction ducts (15) (16) located at the front and back ends of the nozzle and which are hollow elements, that at their top end have a rectangular portion that extends down with a trapezoidal portion whose lower end, at its lower end, ends with a cylindrical tube (6) (7).

12. The aerosol injection nozzle according to claim 11, wherein the nozzle has a size that gradually changes in the front section from a small dimension (101), at an entrance of the nozzle, until a large dimension (100) at an exit of the nozzle.

13. The aerosol injection nozzle according to claim 11, wherein the nozzle has a size that gradually changes in a transverse plane from a large dimension (101) at an entrance of the nozzle, until a small dimension (102) at an exit of the nozzle.

14. A method to use an aerosol injection nozzle to vertically deposit different coatings comprising vertically injecting an aerosol mist from a precursor solution carried out in a nebulizer (1) placed underneath of the aerosol injection nozzle.

15. The method according to claim 14, wherein the aerosol mist of the precursor solution is transported by a carrier gas and is distributed by the injection nozzle.

16. The method according to claim 14, wherein the method deposits materials in the form of coatings, multilayers, material compounds, nanopins, nanovarillas, nanoracimos, nanoplatos, nanowires, nanoparticles, “quantum dots”,
the material is selected from the group consisting of oxides TiO₂, ZnO, ZrO₂, SnO₂ , CuO, NiO, CrOx, AlOx, PbZrTiO₃, LiNbO₃; noble metals, Ag, Au, Pt;
polymer PANI, PEDOT, and mixture thereof;
wherein the method uses chemical vapor deposition process.

17. The method according to claim 14 comprising the following steps:
obtaining the aerosol injection nozzle of claim 11;
preparing a solution including:
a precursor salt of material selected from the group consisting of chloride, nitrate, acetylacetonate, acetate, or a homogeneous dispersion of nanoparticles, and
a solvent, the solvent material selected from the group consisting of methanol, ethanol, distilled water, or a mixture of them;
attaching a substrate to a mobile system (5) and setting a travel speed of a belt or chain conveyor on the mobile system to a predetermined speed;
heating the heating plate (4) between 100 and 900° C.;
introducing a carrier gas into the nozzle;
placing the solution into the nebulizer (1);
nebulizing the solution to transform into a mist of fine drops;
transporting the mist from the nebulizer (1) to the nozzle (2) simultaneously with starting the moving of the mobile system; and
distributing the mist evenly throughout the substrate.

18. The method according to claim 17, further including repeating the deposit process.

19. The method according to claim 17, wherein the heat transfer fins (12) and (13) preheat the aerosol flow before contacting the surface of the substrate.
